(19) United States
(12) Patent Application Publication
(10) Pub. No.: US 2016/0011393 A1
(43) Pub. Date: Jan. 14, 2016

(54) ACTUATOR UNIT AND LENS MODULE

(71) Applicant: Samsung Electro-Mechanics Co., Ltd., Suwon-Si (KR)

(72) Inventors: Jong Beom KIM, Suwon-Si (KR); June Kyoo LEE, Suwon-Si (KR); Hyung Jae PARK, Suwon-Si (KR); Sang Jin KIM, Suwon-Si (KR); Jung Won LEE, Suwon-Si (KR); Hwa Sun LEE, Suwon-Si (KR); Dong Hyun PARK, Suwon-Si (KR)

(73) Assignee: SAMSUNG ELECTRO-MECHANICS CO., LTD., Suwon-Si (KR)

(21) Appl. No.: 14/722,773

(22) Filed: May 27, 2015

(30) Foreign Application Priority Data
Jul. 14, 2014 (KR) 10-2014-0088333
Dec. 12, 2014 (KR) 10-2014-0179301

(51) Int. Cl. G02B 7/09; H01L 41/08; H01L 41/09; G02B 7/28

(52) U.S. Cl. CPC G02B 7/09; G02B 7/282; H01L 41/0825; H01L 41/0946

(57) ABSTRACT

An actuator unit includes a driving part connecting a fixing part and a support part which are disposed to be substantially coplanar; an actuator which is configured to deform the driving part to drive the support part out of the coplanar relationship with respect to the fixing part; and a sensor which is configured to measure a displacement amount or deformation of the driving part.

### CROSS-REFERENCE TO RELATED APPLICATIONS

This application claims benefit under 35 USC 119(a) of Korean Patent Application Nos. 10-2014-0088333, filed on Jul. 14, 2014, and 10-2014-0179301, filed on Dec. 12, 2014 with the Korean Intellectual Property Office, the entire disclosures of which are incorporated herein by reference for all purposes.

### BACKGROUND

1. Field

The following description relates to an actuator unit for driving a lens and a lens module including the same.

2. Description of Related Art

High resolution camera devices commonly include a plurality of lenses and image sensors. Such camera devices frequently include an actuator for moving a lens barrel in an optical axis direction in order to focus lenses to form a clear image.

However, since such an actuator may be required to move the lens barrel, a camera element may have significant mass in order to adjust focal length. Additionally, current consumption may be relatively high and such a structure of the moving lens barrel may be relatively complicated, which is disadvantageous in miniaturizing such camera devices.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an actuator unit includes a driving part connecting a fixing part and a support part disposed to be substantially coplanar; an actuator configured to deform the driving part to drive the support part out of the coplanar relationship with respect to the fixing part; and a sensor configured to measure a displacement amount or deformation of the driving part.

The driving part may be configured to be extended from one side of the fixing part to a center of the support part.

The driving part may be configured to be extended in a tangential direction of the support part from one side of the fixing part.

The driving part may be configured to be connected to the support part while being extended from one side of the fixing part to be parallel to a plurality of neighboring sides.

The driving part may be disposed in a zigzag manner.

The sensors may include a piezoresistor configured to convert magnitudes of physical deformation of the driving part into electrical signals, and the sensor may be disposed at a points on which maximum amounts of stress are exerted in the driving part.

The actuators may include a piezoelectric element.

The driving part may include a first portion configured to have the actuator mounted thereon and be insensitive to deformation due to driving force of the actuator; and a second portion configured to be sensitive to the deformation due to the driving force of the actuator.

The second portion may be formed to be curved.

The sensor may include a surface acoustic wave sensor.

The surface acoustic wave sensor may include a piezoelectric substrate; an input terminal electrode disposed on the piezoelectric substrate configured to generate frequencies depending on deformation of the driving parts; and an output terminal electrode configured to transmit electrical signals by selectively reflecting a portion of the frequencies of the input terminal electrode.

The surface acoustic wave sensor may include a sound-absorbing material blocking noise components from being transferred to the input terminal electrode and the output terminal electrode.

In another general aspect, a lens module includes a housing accommodating a lens; an actuator unit including a support part supporting the lens, driving parts configured to adjust a gradient and/or a focal length of the lens, and actuators disposed on the driving parts; and sensors configured to sense a change in a distance between the housing and the driving parts.

The lens module may include stoppers disposed in the housing to limit a maximum displacement of the driving parts.

The lens module may also include magnetic bodies formed in the housing, wherein the sensors are hall elements or piezoresistors sensing magnetic flux depending on a change in distance between the magnetic bodies and the driving parts.

The sensors may be piezoresistors configured to convert magnitudes of physical deformation of the driving parts into electrical signals.

The actuator unit may include a first actuator unit disposed on a first surface of the lens; and a second actuator unit disposed on a second surface of the lens.

The driving part of the first actuator unit and the driving part of the second actuator unit may be extended in different directions.

According to another general aspect, an adjustable planar lens module includes a substrate with a peripherally defined fixing portion and a support portion, the support portion retaining a lens therein to be substantially coplanar with the substrate; and, an electromechanical actuator extends longitudinally between the fixing portion and the support portion, the actuator being free on at least two longitudinally extending sides thereof and configured to selectively adjust an orientation of the lens and support portion relative to the fixing portion responsive to a driving signal.

The electromechanical actuator may be disposed on a deformable driving portion and a plurality of electrodes may pass therethrough to electrically couple a sensor disposed proximate the support portion to the peripherally defined fixing portion. The electromechanical actuator may be configured to adaptively adjust a focal distance and gradient angle of the lens relative to the fixing portion.

### BRIEF DESCRIPTION OF DRAWINGS

FIG. 1 is a plan view of an exemplary actuator unit;

FIG. 2 is a cross-sectional view of the actuator unit shown in FIG. 1 taken along line A-A;

FIG. 3 is a cross-sectional view of the actuator unit shown in FIG. 1 taken along line B-B;

FIG. 4 is a cross-sectional view of the actuator unit shown in FIG. 1 taken along line C-C;

FIG. 5 is a cross-sectional view of the actuator unit shown in FIG. 1 taken along line D-D;

FIGS. 6 and 7 are cross-sectional views showing an operation state of the actuator unit shown in FIG. 1 taken along line D-D;

FIGS. 8 and 9 are cross-sectional views showing another operation state of the actuator unit shown in FIG. 1 taken along line D-D;

FIG. 10 is a plan view of another exemplary actuator unit;

FIG. 11 is a plan view of an example actuator unit;

FIG. 12 is a plan view of an example actuator unit;

FIG. 13 is a plan view of another example actuator unit;

FIG. 14 is a plan view of an actuator unit;

FIG. 15 is a plan view of another actuator unit;

FIG. 16 is a plan view of an actuator unit;

FIG. 17 is an exploded perspective view of an exemplary lens module;

FIG. 18 is a coupled perspective view of the lens module shown in FIG. 17;

FIG. 19 is a cross-sectional view of the lens module shown in FIG. 18 taken along line E-E;

FIG. 20 is a cross-sectional view of another exemplary lens module taken along line E-E;

FIG. 21 is a cross-sectional view of a lens module taken along line E-E;

FIG. 22 is an exploded perspective view of a lens module;

FIG. 23 is a coupled perspective view of the lens module shown in FIG. 22;

FIG. 24 is a cross-sectional view of the lens module shown in FIG. 23 taken along line F-F;

FIG. 25 is a cross-sectional view of the lens module shown in FIG. 23 taken along line G-G;

FIG. 26 is a plan view of another exemplary lens module;

FIG. 27 is an enlarged view of the part H shown in FIG. 26;

FIG. 28 is a plan view of another exemplary lens module;

FIG. 29 is an enlarged view of the part J shown in FIG. 27 in which an exemplary surface acoustic wave sensor is mounted; and

FIG. 30 is an enlarged view of the part J shown in FIG. 27 in which another exemplary surface acoustic wave sensor is mounted.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art. In the drawings, the shapes and dimensions of elements may be exaggerated for clarity, and the same reference numerals will be used throughout to designate the same or like elements.

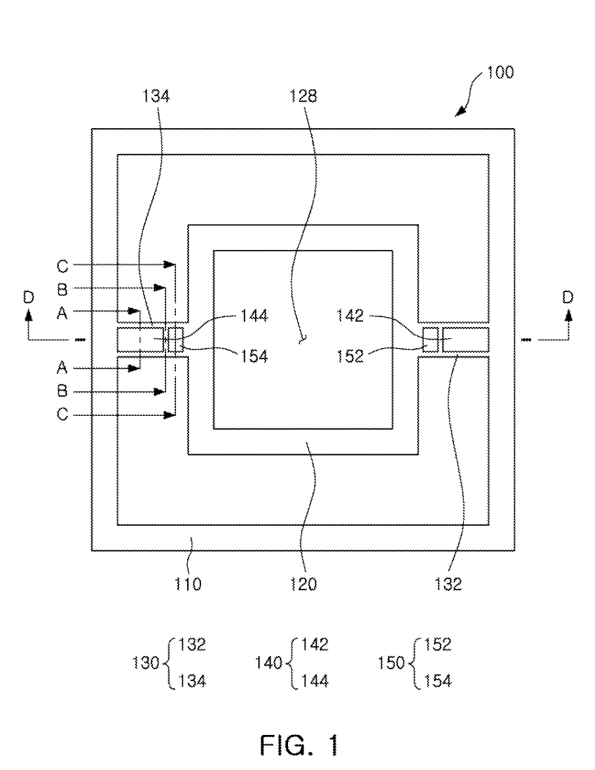

An exemplary actuator unit will be described with reference to FIG. 1.

The actuator unit 100 includes a fixing part 110, a support part 120, and a driving part 130. Further, the actuator unit 100 includes an actuator 140 and a sensor 150 formed in the driving part 130.

The actuator unit 100 may be manufactured based on a wafer. For example, the fixing part 110, the support part 120, and the driving part 130: 132 and 134 of the actuator unit 100 may be integrally formed by a machining process of the wafer. Therefore, a plurality of actuator units 100 may be collectively produced by using a single wafer.

The actuator unit 100 may be generally manufactured in a polygonal shape. For example, the actuator unit 100 may be manufactured in a square. However, the shape of the actuator unit 100 is not limited to the square. For example, the actuator unit 100 may be formed into shapes such as a pentagon, octagon, and a hexagon.

Hereinafter, the fixing part 110, the support part 120, and the driving part 130: 132 and 134 of the actuator unit 100 will be described.

The fixing part 110 may be formed in a form in which four sides thereof are closed. For example, the fixing part 110 may have a square shape. The fixing part 110 formed as described above may be coupled to a housing, a lens barrel, an integrated circuit-board, and the like. The fixing part may be a point-source connection.

The support part 120 is formed in an inner side of the fixing part 110. The support part 120 may have a shape similar to the fixing part 110. By way of example, in FIG. 1, the support part 120 may have the square shape, similar to the fixing part 110. The support part 120 may have a hole 128 formed in a center thereof so that effective light of the lens may pass through. For reference the hole 128 may be changed to a quadrangular shape, pentagon, hexagon, octagon, a circular shape, a point connection, or the like. The support part 120 configured as described above may provide a space in which the lens may be disposed.

The driving part 130: 132 and 134 may connect the fixing part 110 and the support part 120 to each other. For example, the driving part 130: 132 and 134 may be extended from the fixing part 110 to the support part 120, so as to connect the fixing part 110 and the support part 120 which are spatially separated to each other. For reference, the driving part 130: 132 and 134 may be formed of two driving parts, each of which connects sides facing each other of the fixing part 110 and the support part 120. By way of example, the driving part 130: 132 and 134 may be extended from a bisection point of one side of the fixing part 110 to a bisection point of one side of the support part 120.

Next, the actuator 140: 142 and 144 and the sensor 150: 152 and 154 of the actuator unit 100 will be described.

The actuator 140: 142 and 144 may be formed on the driving part 130: 132 and 134. For example, the actuator 140: 142 and 144 may be each formed on two driving parts 130: 132 and 134 respectively. The actuator 140: 142 and 144 may be configured to deform the driving part 130: 132 and 134 in response to an electrical signal. To this end, the actuator 140: 142 and 144 may include a piezoelectric element converting the electrical signal into physical force. However, a motive source of the actuator 140: 142 and 144 is not limited to the piezoelectric element but may be a linear actuator, a drive motor, or the like. The actuator 140: 142 and 144 may be formed to extend in a direction along a length of the driving part 130: 132 and 134. The actuator 140: 142 and 144 configured as described above may significantly increase a displacement difference between one end and the other end of the driving part 130: 132 and 134.

The sensor 150 may be configured to sense a position change depending on the deformation of the driving part 130: 132 and 134. For example, the sensor 150: 152 and 154 may be formed at connection points between the driving part 130: 132 and 134 and the support part 120, so as to sense a position change of the corresponding connection point. For reference, the sensor 150: 152 and 154 may be a hall element sensing magnetic flux. Further, the sensor 150: 152 and 154 may be a piezoresistor converting the physical deformation of the driving part 130: 132 and 134 into the electrical signal.

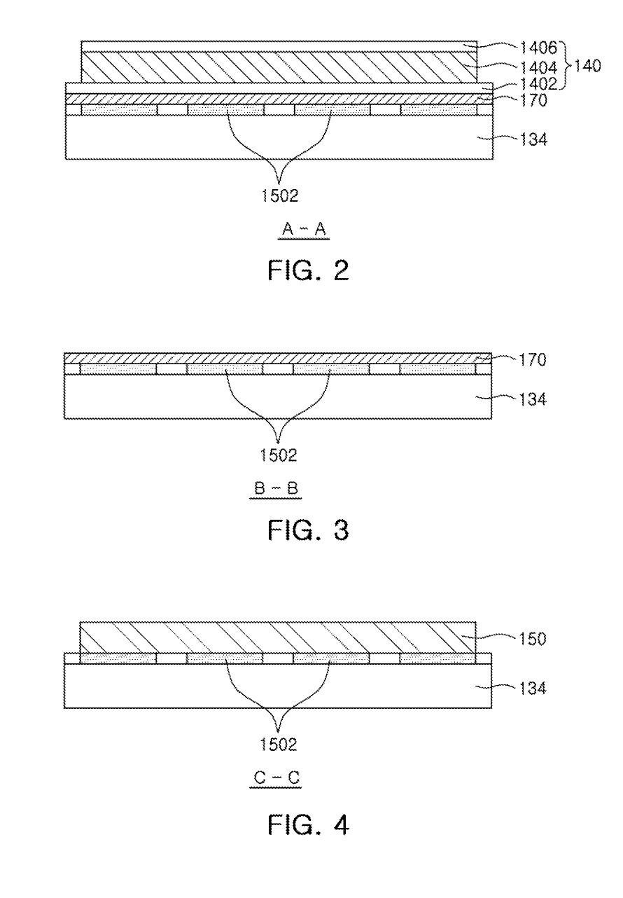

A structure of a cross section of the driving part 134 taken along line A-A will be described with reference to FIG. 2.

The cross section shown in FIG. 2 shows a portion in which the actuator 144 is formed on the driving part 134. This portion may include the driving part 134 made of a wafer material, an electrode layer in which a plurality of electrodes 1502 are formed, an insulating layer 170, a lower electrode 1402, a piezoelectric element 1404, and an upper electrode 1406, as shown in FIG. 2. Here, the plurality of electrodes 1502 are a configuration for a connection with the sensor 154, and the lower electrode 1402 and the upper electrode 1406 are configurations for transmitting the electrical signal to the piezoelectric element 1404. Positions and functions of the electrodes 1402, 1404, and 1502 are not limited to those as described above but may be switched, combined, interposed, multiplexed, altered, or separated. For example, a signal electrode for the sensor 154 may also be formed on the lower electrode 1402 and a signal electrode for the sensor 154 may also be formed on the upper electrode 1404.

A structure of a cross-section of the driving part 134 taken along line B-B will be described with reference to FIG. 3.

The cross section shown in FIG. 3 shows a portion between the actuator 144 and the sensor 154 on the driving part 134. This portion includes the driving part 134, an electrode layer in which a plurality of electrodes 1502 are formed, and an insulating layer 170.

A structure of a cross section of the driving part 134 taken along line C-C will be described with reference to FIG. 4.

The cross section shown in FIG. 4 shows a portion in which the sensor 154 is formed on the driving part 134. This portion includes the driving part 134, a plurality of electrodes 1502, and the sensor 154, as shown in FIG. 4. Here, the plurality of electrodes 1502 may be connected to the sensor 154, so as to transmit a signal sensed by the sensor 154 external thereto such as a controller, processor, feedback circuit, or the like.

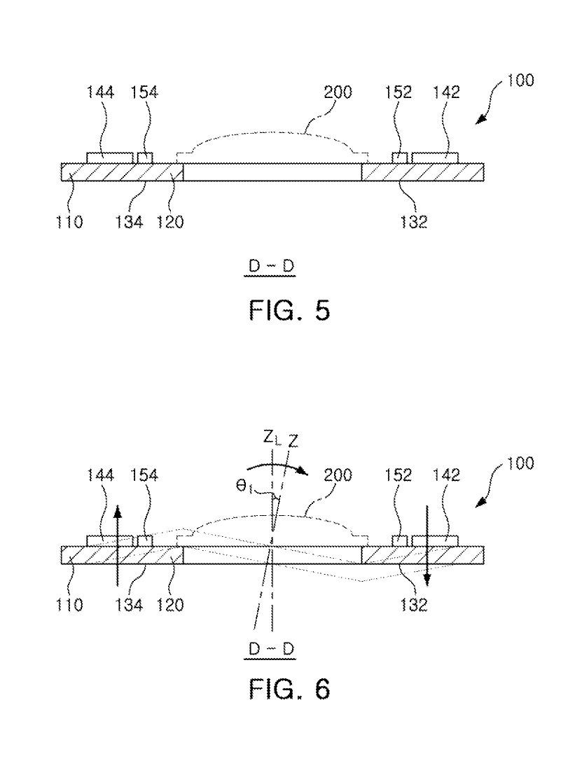

A shape of a cross section of the actuator unit taken along line D-D will be described with reference to FIG. 5.

The actuator unit 100 may have a shape of the cross section shown in FIG. 5. The fixing part 110, the support part 120, and the plurality of driving parts 132 and 134 may be formed by a single wafer as described above, so as to be integrally connected without particularly classifying a boundary therebetween. Therefore, the exemplary actuator unit 100 may advantageously secure coupling reliability between the fixing part 110, the support part 120, and the driving parts 132 and 134. In addition, since the actuator unit 100 may be manufactured based on the wafer, the fixing part 110, the support part 120, and the driving parts 132 and 134 may be advantageously thinned.

The actuators 142 and 144 may be each formed on the driving parts 132 and 134 respectively. By way of example, the actuators 142 and 144 may be formed to extend from connection points between the fixing part 110 and the driving parts 132 and 134 to connection points between the driving parts 132 and 134 and the support part 120. In other words, the actuators 142 and 144 may extend from an outer periphery of the wafer of actuator unit 100 to an inner portion thereof where a lens element 200 is retained. The actuators 142 and 144 configured as described above may collectively, individually, or in opposing manner respectively deform the driving parts 132 and 134 in an upwards, downwards, angular, or translational direction (relative to the orientation shown in FIG. 5) to change a position of a lens 200 disposed on the support part 120. With other configurations, additional directionality may be available.

Although the actuators 142 and 144 are formed on only one surface (upper surface) of the driving parts 132 and 134 in the accompanying drawings, the actuators 142 and 144 may be formed on both surfaces (i.e., upper surface and lower surface) of the driving parts 132 and 134. Additionally, actuators 142 and 144 may also be formed on lateral surfaces as well to provide a broader range of motion.

The sensors 152 and 154 may be each formed on the driving parts 132 and 134. By way of example, the sensors 152 and 154 may be formed at portions to which the driving parts 132 and 134 and the support part 120 are connected. However, the formation positions of the sensors 152 and 154 are not limited to those described above. As another example, the sensors 152 and 154 may also be formed at any portions such as the connection points between the driving parts 132 and 134 and the fixing part at which the displacement is able to be suitably measured.

Next, an exemplary operation state of the actuator unit 100 configured as described above will be described.

In the case in which error occurs during a process of manufacturing the lens 200 or forming the lens 200 on the support part 120, an optical axis ZL-ZL of the lens 200 and an optical axis Z-Z of the lens module may not be matched resulting in a defective unit. However, the exemplary actuator unit 100 may adaptively re-calibrate the above-mentioned state. For example, the actuator unit 100 may adjust a gradient of the support part 120 for the fixing part 110 by deforming the driving part 130, thereby matching the optical axis ZL-ZL of the lens 200 and the optical axis Z-Z of the lens module.

For example, a case in which the optical axis ZL-ZL of the lens 200 is inclined at a first angle θ1 relative to the optical axis Z-Z of the lens module will be described with reference to FIG. 6.

FIG. 6 shows a state in which the optical axis ZL-ZL of the lens 200 is inclined at the first angle θ1 in a counterclockwise direction to the optical axis Z-Z of the lens module. In this case, if the actuator 142 is operated so that the driving part 132 is deformed in a downwards direction and the actuator 144 is operated so that the driving part 134 is deformed in an upwards direction, the optical axis ZL-ZL of the lens 200 and the optical axis Z-Z of the lens module may be matched for corrective alignment. Further, whether or not the optical axis ZL-ZL of the lens 200 and the optical axis Z-Z of the lens module are suitably aligned may be checked by the displacements of the driving parts 132 and 134 sensed by the sensors 152 and 154. Additionally and/or alternatively, an optical feedback may be employed using output from the image sensor itself to supplement sensors 152 and 154.

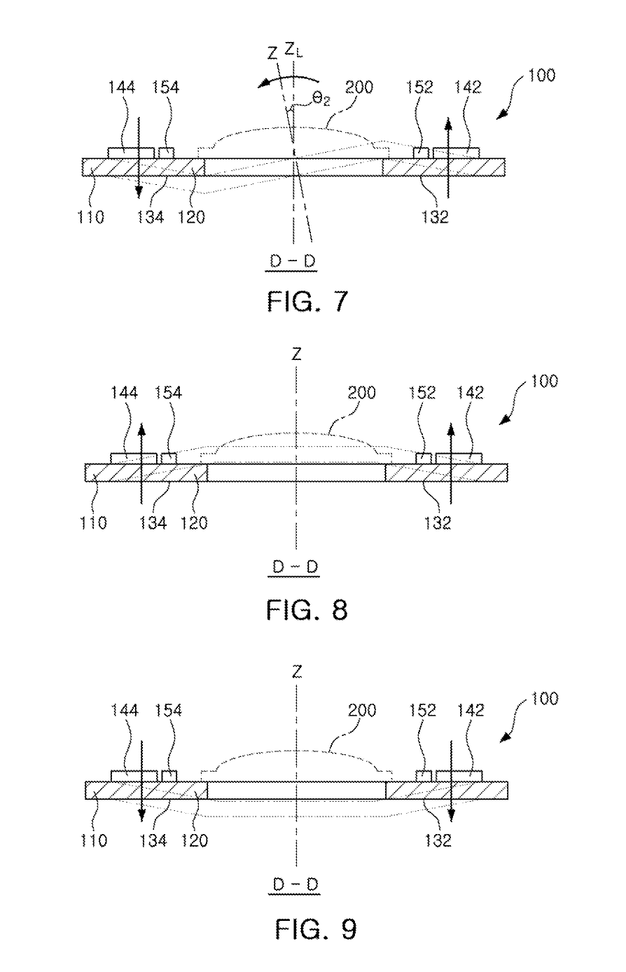

As another example, a case in which the optical axis ZL-ZL of the lens 200 is inclined at a second angle θ2 to the optical axis Z-Z of the lens module will be described with reference to FIG. 7.

FIG. 7 shows a state in which the optical axis ZL-ZL of the lens 200 is inclined at the second angle θ2 in a clockwise direction to the optical axis Z-Z of the lens module. In this case, if the actuator 142 is operated so that the driving part 132 is deformed in an upward direction and the actuator 144 is operated so that the driving part 134 is deformed in a downward direction, the optical axis ZL-ZL of the lens 200 and the optical axis Z-Z of the lens module may be matched. Further, whether or not the optical axis ZL-ZL of the lens 200 and the optical axis Z-Z of the lens module are matched may be determined by the displacements of the driving parts 132 and 134 sensed by the sensors 152 and 154 with optional supplement from the optical sensor.

Next, another operation state of the actuator unit 100 will be described.

The actuator unit 100 according to the present example may be operated collectively so as to adjust a focal distance of an optical system. For example, the actuator unit 100 may be operated so as to increase a distance between the lens 200 and an image plane by moving the lens 200 towards a subject along an axial Z direction. Alternatively, the actuator unit 100 may be operated so as to decrease the distance between the lens 200 and the image plane by moving the lens 200 to the image plane side away from the subject and towards an image sensor or further optical elements.

A method of adjusting an auto-focus distance by the actuator unit 100 will be described with reference to FIGS. 8 and 9.

Sharpness of a subject image focused on the image plane may be determined by the focal distance of the optical system and the focal distance of the optical system may be changed by a distance between the lens 200 and the image plane. Therefore, by adjusting the distance between the lens 200 and the image plane, effective resolution and clarity of the optical system may be substantially improved.

The actuator unit 100 may adjust the focal distance of the optical system in order to improve resolution of the optical system.

By way of example, in the case in which the focal distance of the optical system needs to be increased, the actuators 142 and 144 may be operated so that the driving parts 132 and 134 are both deformed towards the subject side (an upper side based on FIG. 8) as shown in FIG. 8. In this case, the lens 200 may be moved to the subject side which results in the lens 200 being moved away from the image plane of the image sensor disposed therebelow.

As another example, in the case in which the focal distance of the optical system needs to be decreased, the actuators 142 and 144 may be operated so that the driving parts 132 and 134 are deformed towards the image plane side (a lower side based on FIG. 9) as shown in FIG. 9. In this case, the lens 200 may be moved to the image plane side.

The operations of the driving parts 132 and 134 and the actuators 142 and 144 as described above may be adjusted based on electrical signals of the sensors 152 and 154 and an image sensor (not shown). For example, the driving parts 132 and 134 and the actuators 142 and 144 may continuously adjust the position of the lens 200 so that the optical system has a substantially optimal (or at least improved) focal distance employing any suitable auto-focus algorithm known to one of skill in the art to continuously and adaptively adjust focal distance responsive to a shutter button, facial recognition, text recognition, periodically, or combinations thereof.

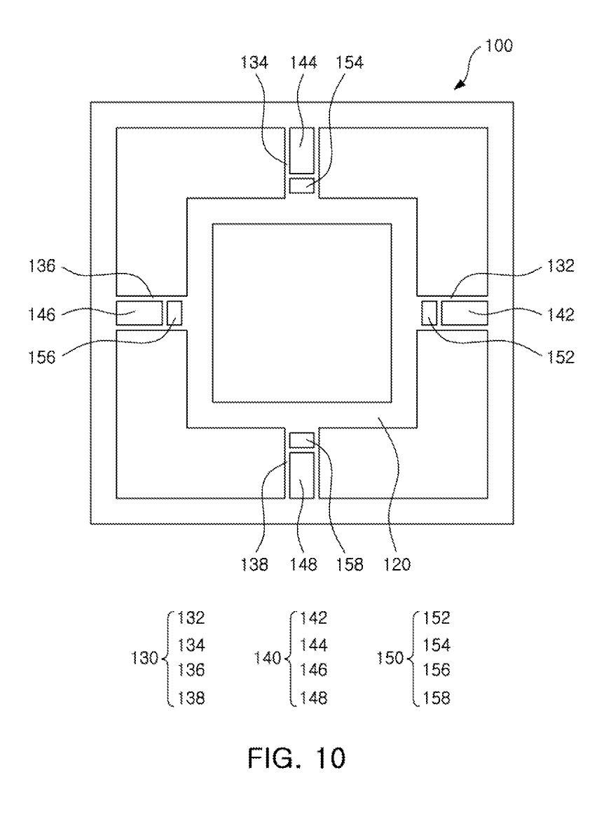

Next, another exemplary actuator unit 100 will be described with reference to FIG. 10.

The actuator unit 100 may differ from the actuator unit 100 described above in that it has 5 degrees of freedom provided by two transverse driving part pairs 130: 132, 134, 136, and 138. The respective driving parts 130: 132, 134, 136, and 138 which extended from the respective sides of the fixing part 110 to the sides of the support part 120 facing the fixing part 110.

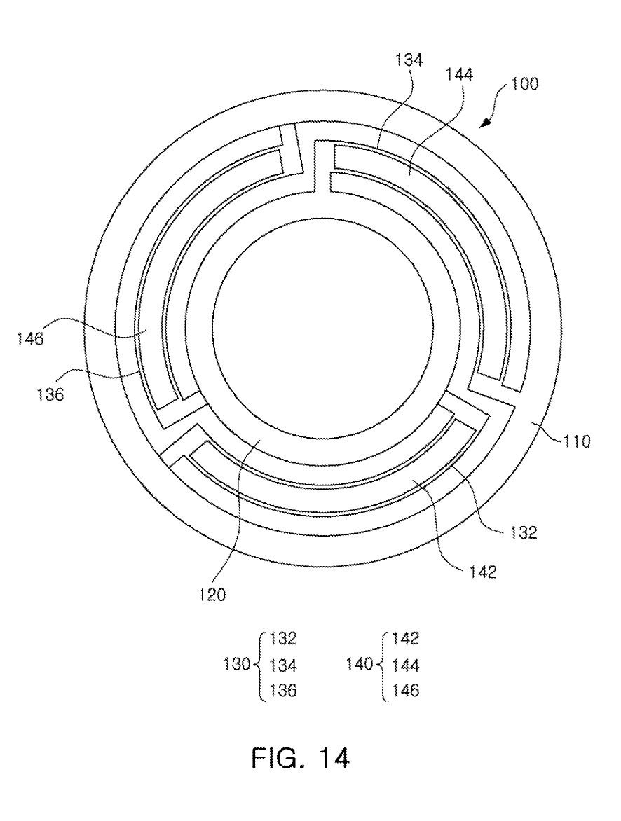

Since the actuator unit 100 having the configuration described above has the fixing part 110 and the support part 120 connected by a plurality of driving parts 130: 132, 134, 136, and 138, connection reliability between the fixing part 110 and the support part 120 may be increased. Further, since the actuator unit 100 includes a plurality of transversely disposed actuator pairs 140: 142, 144, 146, and 148, a gradient of the support part 120 to the fixing part 110 may be rapidly adjusted in an X or Y rotation and/or translation and a Z-distance translation. While the various exemplary actuator units 100 shown herein generally include pairs of actuators 140, an odd number of actuators, such as seen in FIG. 14 is also contemplated herein. Moreover, while some shock absorption and degrees of articulable freedom may be sacrificed, the actuator unit 100 may employ only one actuator 140 which may also serve as the driving part 130 and as the sensor 150, such as, for example, in time-multiplexed manner between actuation and sensing.

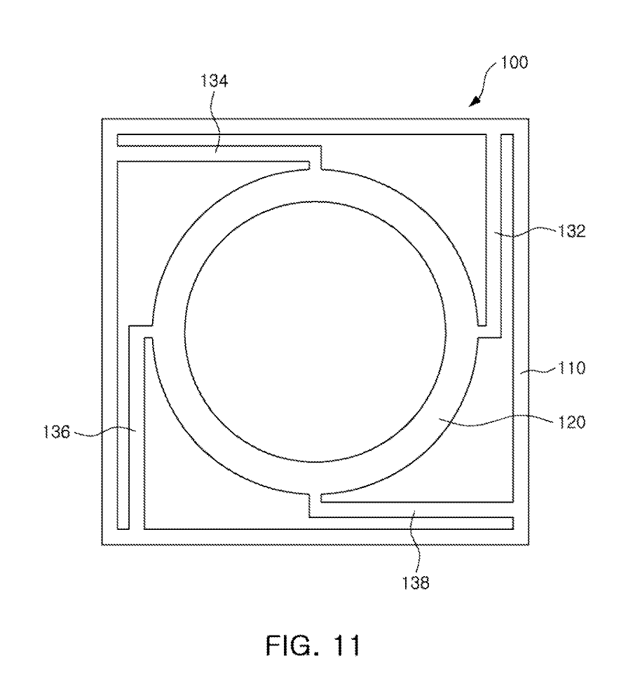

Another exemplary actuator unit 100 will be described with reference to FIG. 11. The actuator unit 100 differs from the actuator units 100 described above in that the support part 120 has a substantially circular shape. Further, the actuator unit 100 differs from the actuator units 100 described above in that the driving parts 130: 132, 134, 136, and 138 are extended from the fixing part 110 in respectively tangential directions of the support part 120.

Such shape may secure the driving parts 130: 132, 134, 136, and 138 having a significant length, thereby improving displacement widths of the driving parts 130: 132, 134, 136, and 138 to provide greater range of translational and rotational motion. For reference, the actuators 140: 142, 144, 146, and 148 (not shown) may be formed on the respective driving parts 130: 132, 134, 136, and 138. However, the actuators 140 may be omitted from one or more of the driving parts 130.

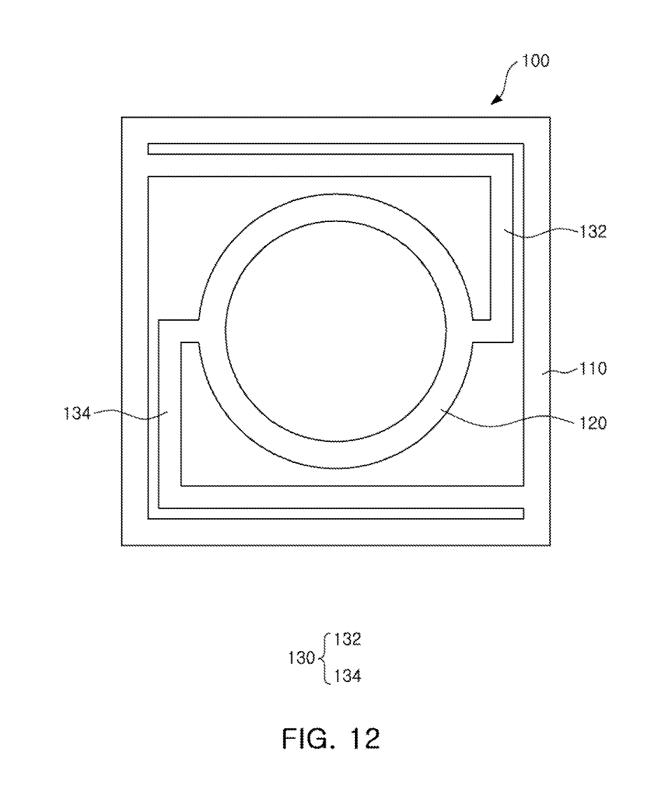

Another exemplary actuator unit 100 will be described with reference to FIG. 12 below. The actuator unit 100 differs from the actuator units 100 described above in that the driving parts 130: 132 and 134 have shapes which are extended transversely in two or more different directions. By way of example, the driving parts 130: 132 and 134 may be connected to the support part 120 while being extended from one side of the fixing part 110 so as to be substantially in parallel to two neighboring sides. The actuators 140: 142 and 144 may be formed on the respective driving parts 130: 132 and 134.

Such shape may secure the driving parts 130: 132 and 134 having an extended length to thereby improving displacement widths of the driving parts 130: 132 and 134 to provide a greater range of translational and rotational motion.

Further, the actuator unit 100 may deform the driving parts 130 in a horizontal direction by adjusting the number and arrangement shape of actuators formed on the driving parts 130: 132 and 134.

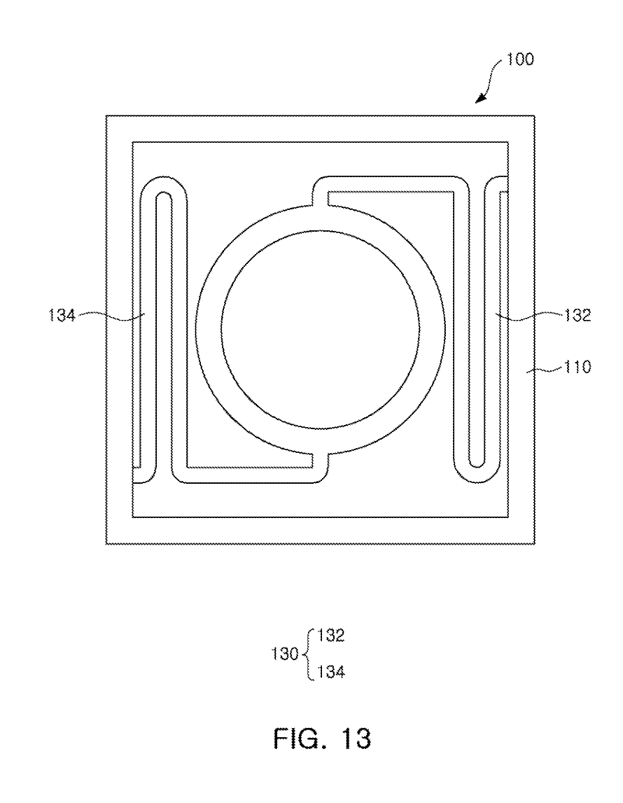

Another exemplary actuator unit 100 will be described with reference to FIG. 13. The actuator unit 100 differs from the actuator units 100 described above in that the driving parts 130: 132 and 134 have a curved, meandering, or undulating shape to both absorb shock and to provide yet greater deformability to afford yet greater range of translational and rotational motion. In the actuator unit 100 having such shape, the driving parts 130: 132 and 134 may absorb impact applied to the support part 120. For reference, the actuators 140: 142 and 144 (not shown) may be formed on the respective driving parts 130: 132 and 134.

Another exemplary actuator unit 100 will be described below with reference to FIG. 14. The actuator unit 100 differs from the actuator units 100 described above in that a shape of the fixing part 110 may also be circular and arranged in a concentric or coaxial arrangement with the support part 120. The driving part 130 may have a curved shape having a predetermined radius.

Since the actuator unit 100 having such shape has the fixing part 110 and the support part 120 having the circular shape, the number and formation position of driving parts 130 may be easily adjusted. For example, as shown in FIG. 14, the number of driving parts 130 may be changed to one, two, three, or may be adjusted to five or more. Meanwhile, the actuators 140: 142, 144, and 146 may be formed on or serve as the respective driving parts 130: 132, 134, and 136.

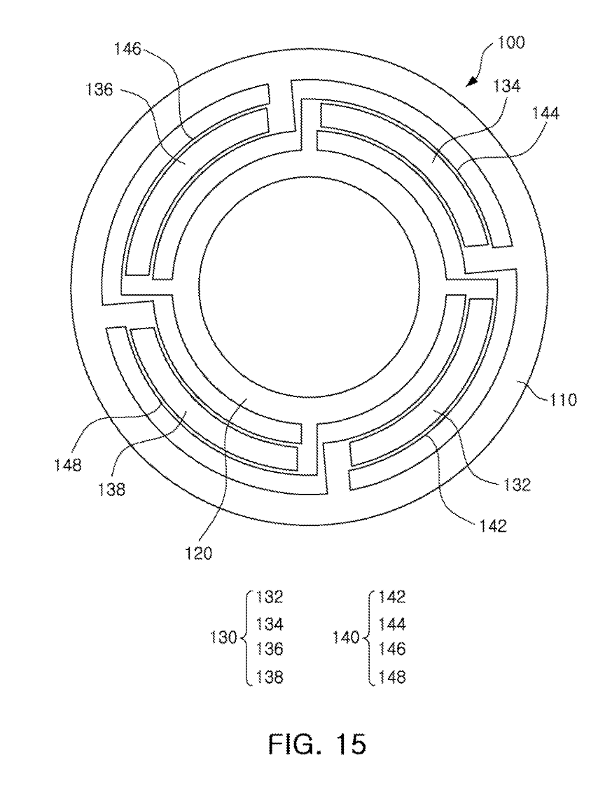

Another exemplary actuator unit 100 will be described below with reference to FIG. 15. The actuator unit 100 differs from the form shown in FIG. 14 in the number of driving parts 130. By providing two transversely disposed pairs 132 and 136; and 134 and 138, translation and rotation in at least two axes e.g. X and Y may be beneficially provided. That is, the actuator unit 100 has the fixing part 110 and the support part 120 connected by four driving parts 130 including the two matched transverse pairs. The actuators 140: 142, 144, 146, and 148 may be formed on the respective driving parts 130: 132, 134, 136, and 138. However, the actuators 140 are not necessarily formed on all the driving parts 130. For example, the actuators may not be formed on some driving parts e.g. 132 and 136 or 134 and 138.

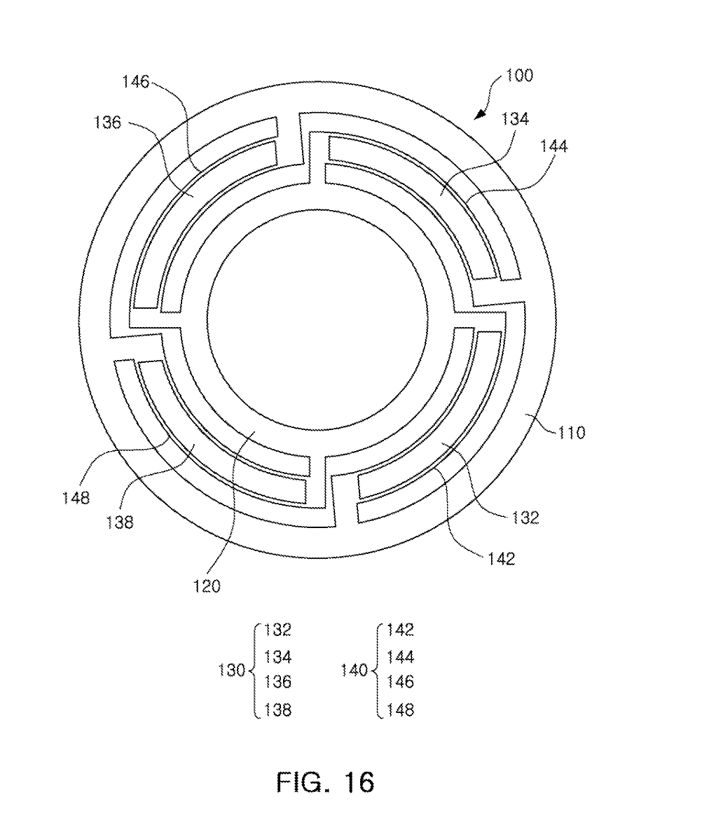

Yet another exemplary actuator unit 100 will be described below with reference to FIG. 16. The actuator unit 100 may differ from the actuator units 100 described above in shapes of the driving parts 130. For example, the driving parts 130 may have a shape in which the driving parts 130 are extended so as to be parallel to a circumferential direction of the support part 120 at a predetermined position while being extended from one side of the fixing part 110 so as to be in parallel to a neighboring side. In other words, the driving parts 130 are formed as arcs being concentrically arranged with respect to the fixing part 110 and support part 120 in coaxial arrangement therewith. Here, the actuators 140: 142, 144, 146, and 148 may be formed on straight line sections or curved line sections of the driving parts 130: 132, 134, 136, and 138.

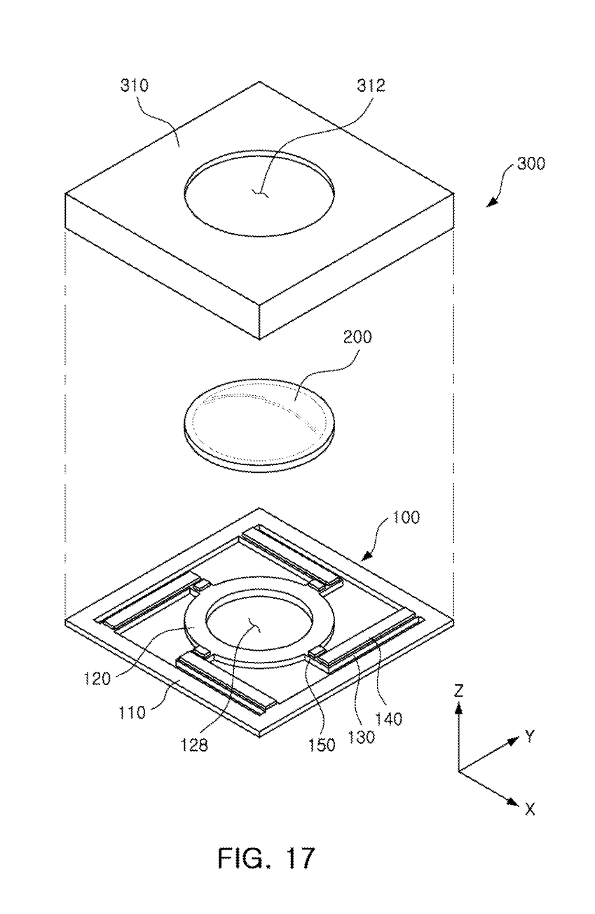

Next, an exemplary lens module will be described with reference to FIG. 17. For reference, although the actuator unit 100 is shown and described in one shape in the accompanying drawings and the specification, the actuator unit 100 may be changed to any one of various exemplary configurations as described above.

The lens module 300 includes an actuator unit 100, a lens 200, and a housing 310. By way of example, the lens module 300 has a structure in which the lens 200 and the actuator unit 100 are coupled to each other within the housing 310.

The actuator unit 100 may be any one of the actuator units described above or combinations thereof. For example, the actuator unit 100 may be substantially the same as or similar to the form shown in FIG. 11. The actuator unit 100 includes a fixing part 110, a support part 120, a driving part 130, an actuator 140, and a sensor 150. The fixing part 110 is configured to be coupled to the housing 310. The fixing part 110 and the housing 310 may be coupled by a bonding, a stationary fitting, or the like. The support part 120 may be coupled to the lens 200. The support part 120 and the lens 200 may be coupled by an adhesive, friction fit, or other suitable measures. The driving part 130 may be deformed so that the support part 120 is movable with respect to the fixing part 110. The driving part 130 may be bent in an upper direction or a lower direction by the actuator 140, so as to allow a tilt correction of the lens 200. The sensor 150 may be formed on the driving part 130, so as to measure a displacement of the driving part 130. By way of example, the sensor 150 may measure a distance between the driving part 110 and one surface (such as the bottom surface) of the housing 310 or an upper surface below the support part 120 and convert the measured distance into an electrical signal so as to transmit the electrical signal.

The lens 200 may be formed on the support part 120. The lens 200 may have positive or negative refractive power so as to properly refract incident effective light. Although only one lens 200 is shown in FIG. 17, two or more lenses 200 may be formed on the support part 120.

The housing 310 is configured to accommodate the actuator unit 100 and the lens 200. The housing 310 may have a hole 312 formed therein to accommodate the lens 200. Alternatively, housing 310 may be formed at least in part of a clear material. By way of example, the hole 312 through which effective light is incident may be formed in one surface of the housing 310 facing the lens 200 or hole 312 may be filled with a clear material or a secondary lens.

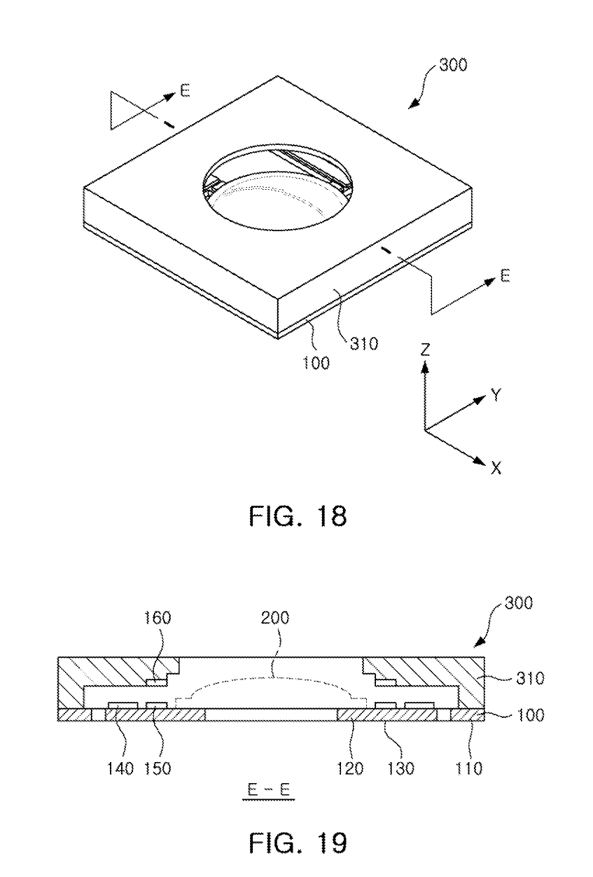

An exemplary coupling form of the lens module 300 will be described with reference to FIG. 18. The lens module 300 may have a rectangular parallelepiped shape which generally has a low height established according to a maximum flexural range of the driving part 130 as shown in FIG. 18. Therefore, the lens module 300 may be easily mounted in a portable terminal, a small electronic device, and the like.

An exemplary cross section shape of the lens module 300 will be described with reference to FIG. 19.

The lens module 300 may be configured to measure a distance from the driving part 130 to the housing 310. By way of example, the lens module 300 includes sensors 150 and magnetic bodies 160. The sensor 150 may be formed on the driving part 130 and the magnetic body 160 may be formed on a portion of the housing 310 which generally faces the sensor 150, such as a bottom surface thereof. Alternatively, the magnetic body 160 and sensor 150 may be reversed to be disposed on the driving part 130 and housing 310 respectively. In yet a further configuration, one of the magnetic body 160 or the sensor 150 may be disposed below or lateral to the driving part 130. Any suitable arrangement for measuring the flexure or displacement of the actuator 140 or driving part 130 may be employed.

The lens module 300 configured as described above may sense a position of the driving part 130 through a change in magnetic flux depending on the distance between the sensor 150 and the magnetic body 160. In addition, the lens module 300 may determine a gradient (or tilt) angle of the lens 200 through the position of one of the driving parts 130 relative to another such as portion 132 relative to 134, 136, or 138. The difference between the distances of an opposing pair may be calculated to determine the inclination or offset angle for correction. For reference, the sensor 150 may be a hall element sensing the magnetic flux of the magnetic body 160.

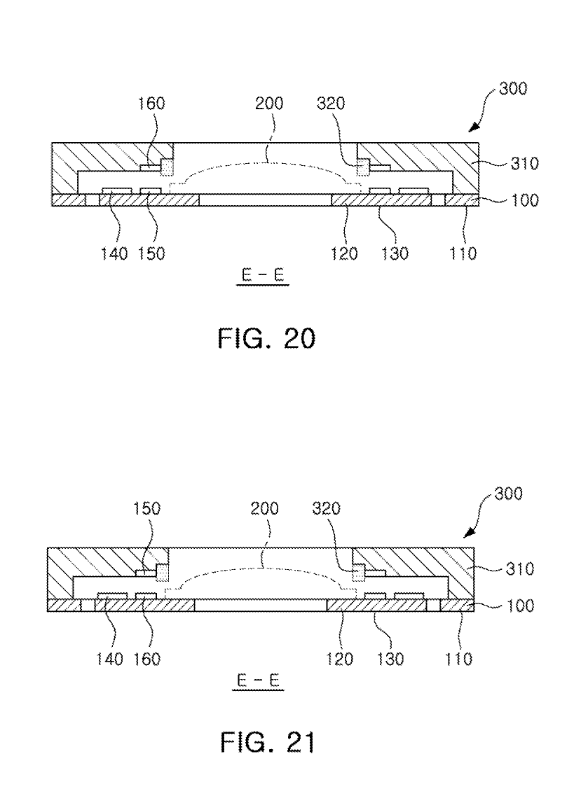

An exemplary cross section shape of the lens module 300 will be described below with reference to FIG. 20. The lens module 300 may further include stoppers 320 as shown in FIG. 20.

The stoppers 320 may be formed in the housing 310 or may be formed on or coupled to the lens 200 or driving part 130. By way of example, the stoppers 320 may be formed so as to generally face the driving parts 130 or edge portions of the lens 200 in the housing 310. The stoppers 320 configured as described above may suppress warpage deformation of the driving parts 130 so that the driving parts 130 are not deformed beyond a set limit range. Meanwhile, the stoppers 320 may be made of a separate material or may be a portion of the housing 310. By way of example, the stoppers 320 may have a protrusion shape protruding from the housing 310 in a lower direction. Stoppers 320 may employ a deformable resilient cushion member to act with increasing force the further they are deformed to gradually restrict the extent of travel of driving part 130.

A cross section shape of another exemplary lens module 300 will be described below with reference to FIG. 21.

The lens module 300 differs from the lens modules 300 described above in that positions of the sensor 150 and the magnetic body 160 are transposed. Since such configuration may omit a layer in the actuator unit 100 on which the electrode 1502 is formed, it may allow the actuator unit 100 to be more easily manufactured, thinner, lighter, and more easily deformed.

For reference, although the lens modules 300 shown in FIGS. 17 through 21 have the configuration in which the housing 310 and the stoppers 320 are formed on one side (an upper side based on FIG. 17) of the lens 200, the housing 310 and the stoppers 320 may be configured so as to be formed on the other side (a lower side based on FIG. 17) of the lens 200.

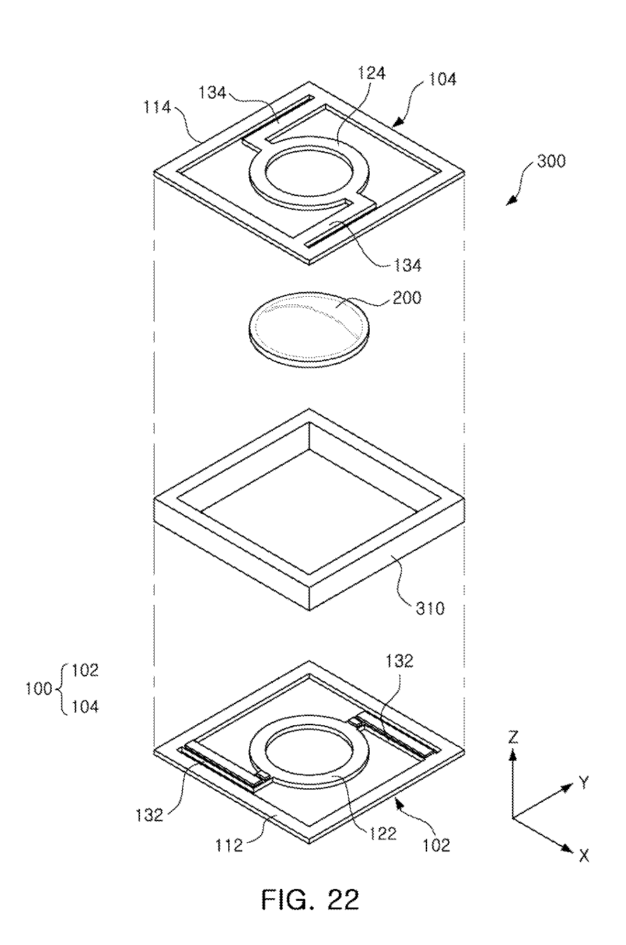

Another exemplary lens module 300 will be described with reference to FIG. 22 below. The lens module 300 may include two (or more) actuator units 102 and 104, one lens 200, and a housing 310. By way of example, the lens module 300 may have a structure in which the two actuator units 102 and 104 are disposed on opposing axial sides of the lens 200 to retain it therebetween.

A first actuator unit 102 includes a fixing part 112, a support part 122, and a driving part 132, and a second actuator unit 104 includes a fixing part 114, a support part 124, and a driving part 134.

The actuator units 102 and 104 may have different operation displacements. For example, the first actuator unit 102 may be configured to rotate the support part 122 or the lens 200 in a Z-Y plane direction, and the second actuator unit 104 may be configured to rotate the support part 124 or the lens 200 in a Z-X plane direction.

The lens module 300 configured as described above may advantageously improve reliability and speed of a tilt correction of the lens 200. For reference, the housing may be used as an interval maintaining measure to maintain a predetermined distance between the first actuator unit 102 and the second actuator unit 104. In such a configuration, the magnetic unit 160 and sensor 150 may be disposed on opposing actuator units or on the housing 310.

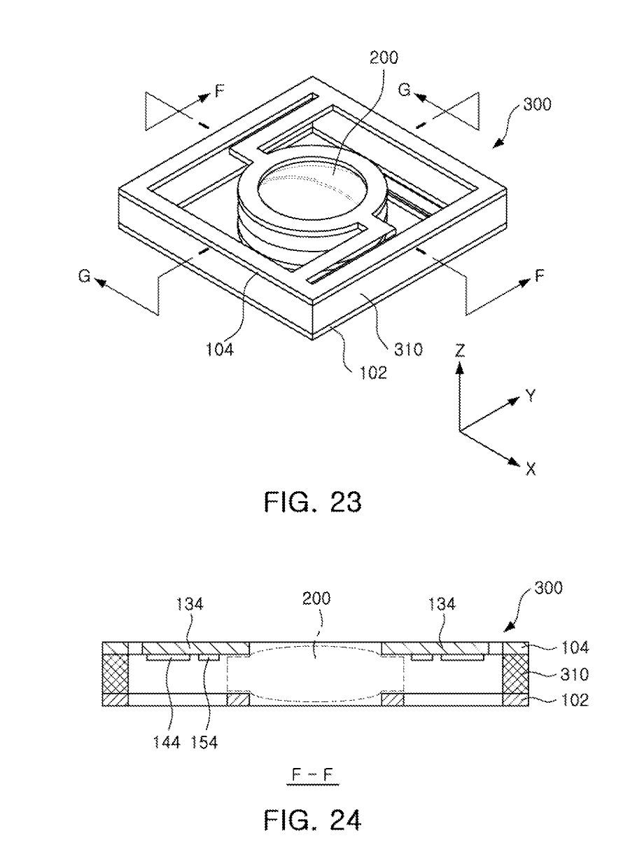

An exemplary coupling shape of a lens module 300 will be described below with reference to FIG. 23. The lens module 300 may be configured such that the first actuator unit 102, the housing 310, the lens 200, and the second actuator unit 104 are sequentially coupled to securely retain the lens 200 therebetween. Since the lens module 300 configured as described above generally has a substantially symmetric upper and lower shape, it may be more easily manufactured.

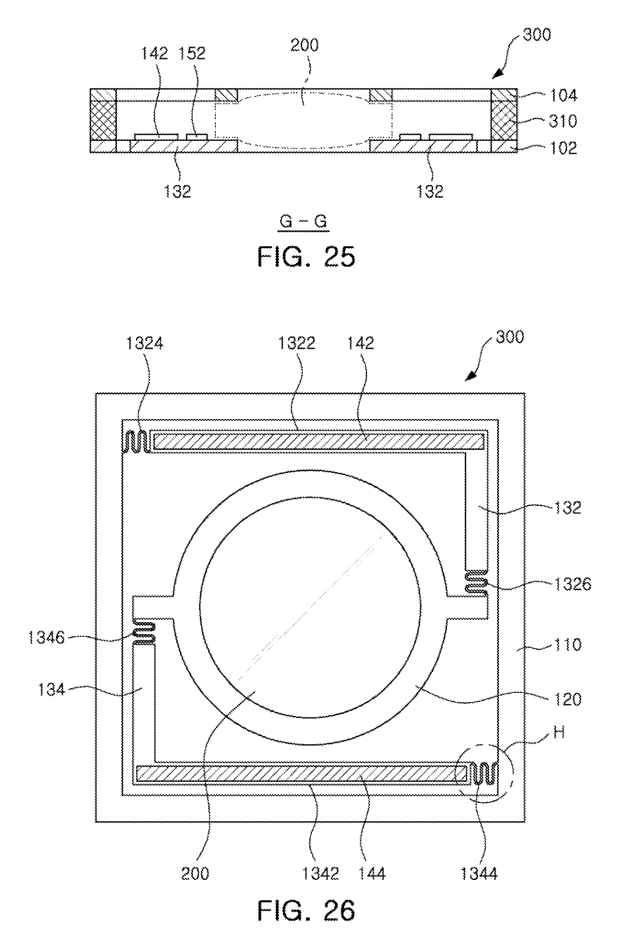

Cross sections of the lens module 300 taken along line F-F and line G-G will be described with reference to FIGS. 24 and 25.

The lens module 300 includes a first actuator unit 102 and a second actuator 104 as shown in FIGS. 24 and 25. The respective actuator units 102 and 104 may include driving parts 132 and 134, and actuators 142 and 144 deforming the driving parts 132 and 134 respectively. In addition, the respective actuator units 102 and 104 may include sensors 152 and 154 for sensing displacements of the driving parts 132 and 134. In the case in which reference numeral 152 indicates a hall element, for example, reference numeral 154 may indicate a magnetic body.

Since the lens module 300 configured as described above has a shape in which the two actuator units 102 and 104 support an upper surface and a lower surface of the lens 200, it may stably support the lens 200 and may accurately adjust an optical axis of the lens 200.

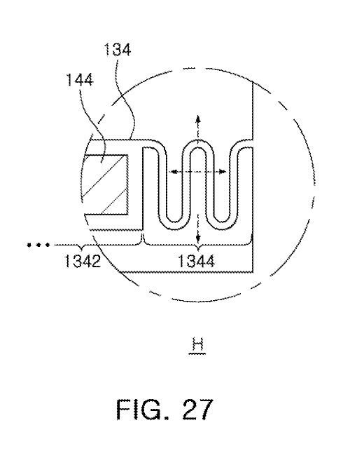

Another exemplary lens module will be described below with reference to FIGS. 26 and 27. A lens module 300 may differ from the lens modules 300 described above in a form of the driving parts 132 and 134. For example, the driving parts 132 and 134 may be configured so as to be easily deformed by the actuators 142 and 144 respectively. By way of example, the driving parts 132 and 134 may be partitioned into hard portions 1322 and 1342 which are relatively stiffer and more difficult to elastically deform and soft portions 1324, 1326, 1344, and 1346 which are more easily elastically deformed.

The hard portions 1322 and 1342 may have a constant thickness and width. Further, the hard portions 1322 and 1342 may generally have cross sectional shapes which are uniform along a length direction of the driving parts 132 and 134.

The hard portions 1322 and 1342 configured as described above may be used as mounting spaces for the actuators 142 and 144.

The soft portions 1324, 1326, 1344, and 1346 may have a thickness or a width smaller than that of the hard portions 1322 and 1342, as shown, for example in FIG. 27. By way of example, the soft portions 1324, 1326, 1344, and 1346 may be portions having a reduced cross section size from the driving parts 132 and 134. As another example, the soft portions 1324, 1326, 1344, and 1346 may be portions having a reduced width from the driving parts 132 and 134. As another example, the soft portions 1324, 1326, 1344, and 1346 may be portions formed in a meandering or undulating curve form from the driving parts 132 and 134.

The soft portions 1324, 1326, 1344, and 1346 may be formed at one or several portions of the driving parts 132 and 134. By way of example, the soft portions 1324, 1326, 1344, and 1346 may be formed at both ends and/or centers of the driving parts 132 and 134. As another example, the soft portions 1324 and 1344 may be formed at portions to which the driving parts 132 and 134 and the fixing part 110 are connected. As another example, the soft portions 1326 and 1346 may be formed at portions to which the driving parts 132 and 134 and the lens support part 120 are connected.

The soft portions 1324, 1326, 1344, and 1346 configured as described above are easily deformed by driving force of the actuators 142 and 144, which enables a position of the lens support part 120 to the fixing part 110 to be easily changed. By way of example, the soft portions 1324, 1326, 1344, and 1346 may be deformed in the optical axis direction by the driving force of the actuators 142 and 144 so as to change a focal distance of the lens module 300. As another example, the soft portions 1324, 1326, 1344, and 1346 may be deformed in a direction perpendicular to the optical axis by the driving force of the actuators 142 and 144 so as to enable a tilt correction or image stabilization of the lens module 300.

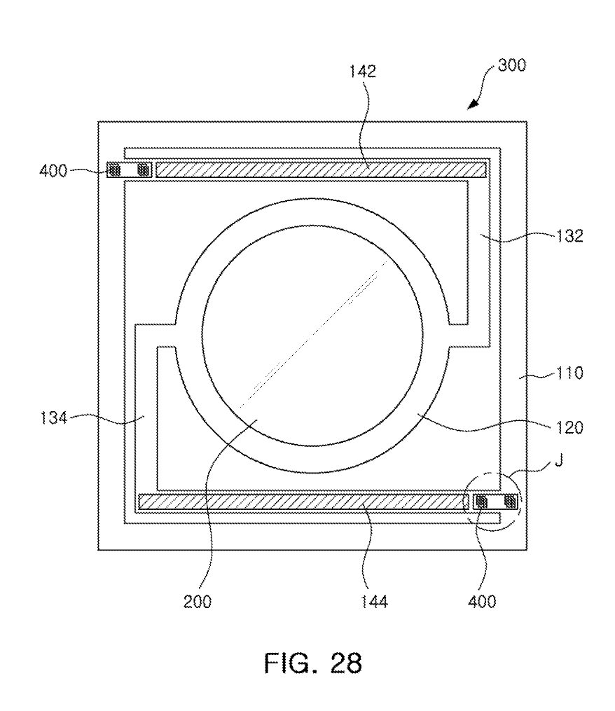

Another exemplary lens module will be described below with reference to FIG. 28. A lens module 300 may differ from the lens modules 300 described above in that it includes a surface acoustic wave sensor 400. By way of example, the surface acoustic wave sensor 400 may be formed on at least one portion of the fixing part 110, the lens support part 120, and/or the driving part 130. As another example, the surface acoustic wave sensor 400 may be formed at a portion to which the fixing part 110 and the driving part 130 are connected. In other words, the surface acoustic wave sensor 400 may be formed at a peripheral boundary between the driving part 132, 134 or the actuator 142, 144 and the fixing part 110. As another example, the surface acoustic wave sensor 400 may be formed at a portion to which the lens support part 120 and the driving part 130 are connected.

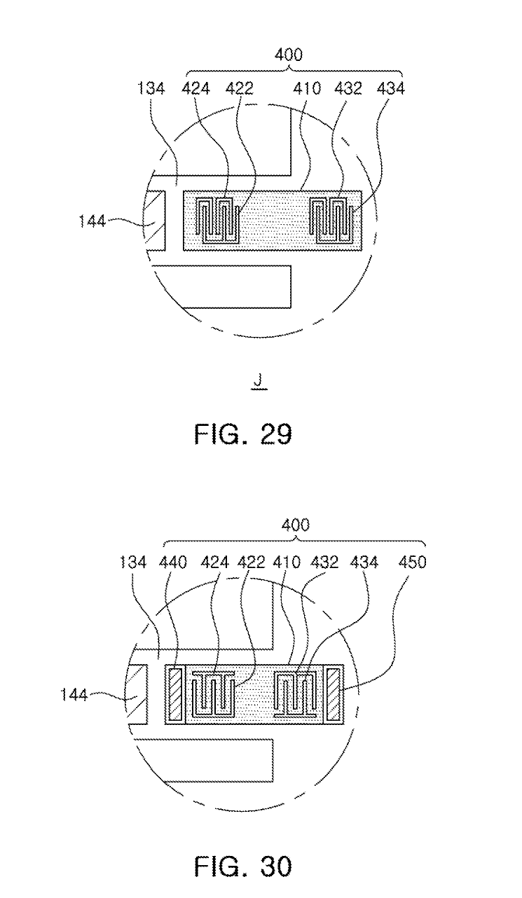

One form of the surface acoustic wave sensor will be described with reference to FIG. 29. The surface acoustic wave sensor 400 may include a piezoelectric substrate 410, input terminal electrodes 422 and 424, and output terminal electrodes 432 and 434. The piezoelectric substrate 410 may serve as a medium transferring an acoustic wave between the input terminal electrodes 422 and 424 and the output terminal electrodes 432 and 434. The input terminal electrodes 422 and 424 may convert deformation energy of the driving part 134 into the acoustic wave and the output terminal electrodes 432 and 434 may sense the acoustic wave and convert it into an electrical signal.

The surface acoustic wave sensor 400 configured as described above may precisely measure a deformed state of the driving part 134 through frequency deviation between the electrodes 422, 424, 432, and 434.

Another exemplary form of the surface acoustic wave sensor will be described below with reference to FIG. 30. The surface acoustic wave sensor 400 having another form may further include sound-absorbing or dampening materials 440 and 450 at one or more peripheral edges thereof. By way of example, a first sound-absorbing material 440 may be formed at a side of the input terminal electrodes 422 and 424 and a second sound-absorbing material 450 may be formed at a side of the output terminal electrodes 432 and 434.

The sound-absorbing materials 440 and 450 configured as described above may remove noise components. Therefore, the surface acoustic wave sensor 400 having the present form may more precisely and accurately measure the deformed state of the driving part 134.

The sensors 150 and 400 may be coupled to one or more controllers to determine an initial displacement, location, flexure, or the like and responsively drive electronic signals to selectively control the actuators 140 herein illustrated in FIGS. 1-30 that perform the operations described herein. For example, a controller initially queries the sensors 150 to determine a distance to magnetic units 160 or the surface acoustic wave sensor 400 to determine an amount of deformation of a driving part 132, 134. Such determination made me made with regards to one driving part 132 and a symmetrically disposed second driving part 134 and/or 136 and 138, or the like. Thereupon, the controller may determine an angular offset of the lens unit (due to defect, shock, or active deformation). Responsive to the determination, the controller may adaptively adjust one or more actuation parts 140 to re-calibrate, refocus, or compensate for shock. The controller may continuously poll the sensors 150, 400 to determine an amount of deformation with such information serving as a feedback to continuously refine adjustment of the lens 200. Such controllers may also be employed to gauge voltage levels of sensors or the actuation parts 140, 142, 144 themselves. The controllers may execute a camera application, an autofocus operation, a facial recognition, text recognition, or the like to both determine and then effect a substantially ideal orientation of the lens 200 for the particular stimuli detected.

Examples of hardware components include controllers, sensors, generators, drivers, and any other electronic components known to one of ordinary skill in the art. In one example, the hardware components are implemented by one or more processors or computers. A processor or computer is implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices known to one of ordinary skill in the art that is capable of responding to and executing instructions in a defined manner to achieve a desired result. In one example, a processor or computer includes, or is connected to, one or more memories storing instructions or software that are executed by the processor or computer. Hardware components implemented by a processor or computer execute instructions or software, such as an operating system (OS) and one or more software applications that run on the OS, to perform the operations described herein. The hardware components also access, manipulate, process, create, and store data in response to execution of the instructions or software. For simplicity, the singular term “processor” or “computer” may be used in the description of the examples described herein, but in other examples multiple processors or computers are used, or a processor or computer includes multiple processing elements, or multiple types of processing elements, or both. In one example, a hardware component includes multiple processors, and in another example, a hardware component includes a processor and a controller. A hardware component has any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods that perform the operations described herein may be performed by a processor or a computer as described above executing instructions or software to perform the operations described herein.

Instructions or software to control a processor or computer to implement the hardware components and perform the methods as described above are written as computer programs, code segments, instructions or any combination thereof, for individually or collectively instructing or configuring the processor or computer to operate as a machine or special-purpose computer to perform the operations performed by the hardware components and the methods as described above. In one example, the instructions or software include machine code that is directly executed by the processor or computer, such as machine code produced by a compiler. In another example, the instructions or software include higher-level code that is executed by the processor or computer using an interpreter. Programmers of ordinary skill in the art can readily write the instructions or software based on the descriptions in the specification, which disclose algorithms for performing the operations performed by the hardware components and the methods as described above.

The instructions or software to control a processor or computer to implement the hardware components and perform the methods as described above, and any associated data, data files, and data structures, are recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any device known to one of ordinary skill in the art that is capable of storing the instructions or software and any associated data, data files, and data structures in a non-transitory manner and providing the instructions or software and any associated data, data files, and data structures to a processor or computer so that the processor or computer can execute the instructions. In one example, the instructions or software and any associated data, data files, and data structures are distributed over network-coupled computer systems so that the instructions and software and any associated data, data files, and data structures are stored, accessed, and executed in a distributed fashion by the processor or computer.

Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation.

As a non-exhaustive example only, a terminal/device/unit as described herein may be a mobile device, such as a cellular phone, a smart phone, a wearable smart device (such as a ring, a watch, a pair of glasses, a bracelet, an ankle bracelet, a belt, a necklace, an earring, a headband, a helmet, or a device embedded in clothing), a portable personal computer (PC) (such as a laptop, a notebook, a subnotebook, a netbook, or an ultra-mobile PC (UMPC), a tablet PC (tablet), a phablet, a personal digital assistant (PDA), a digital camera, a portable game console, an MP3 player, a portable/personal multimedia player (PMP), a handheld e-book, a global positioning system (GPS) navigation device, or a sensor, or a stationary device, such as a desktop PC, a high-definition television (HDTV), a DVD player, a Blu-ray player, a set-top box, or a home appliance, or any other mobile or stationary device capable of wireless or network communication. In one example, a wearable device is a device that is designed to be mountable directly on the body of the user, such as a pair of glasses or a bracelet. In another example, a wearable device is any device that is mounted on the body of the user using an attaching device, such as a smart phone or a tablet attached to the arm of a user using an armband, or hung around the neck of the user using a lanyard.

As set forth above, an auto-focus adjustment may be rapidly and accurately performed. While exemplary embodiments have been shown and described above, it will be apparent to those skilled in the art that modifications and variations could be made without departing from the scope of the present application as defined by the appended claims.

What is claimed is:

1. An actuator unit comprising:
a driving part connecting a fixing part and a support part disposed to be substantially coplanar;
an actuator configured to deform the driving part to drive the support part out of the coplanar relationship with respect to the fixing part; and
a sensor configured to measure a displacement amount or deformation of the driving part.

2. The actuator unit of claim 1, wherein the driving part is configured to be extended from one side of the fixing part to a center of the support part.

3. The actuator unit of claim 1, wherein the driving part is configured to be extended in a tangential direction of the support part from one side of the fixing part.

4. The actuator unit of claim 1, wherein the driving part is configured to be connected to the support part while being extended from one side of the fixing part to be parallel to a plurality of neighboring sides.

5. The actuator unit of claim 1, wherein the driving part is disposed in a zigzag manner.

6. The actuator unit of claim 1, wherein the sensor includes a piezoresistor configured to convert magnitudes of physical deformation of the driving parts into electrical signals, and
the sensor is disposed at a point on which maximum amounts of stress is exerted in the driving part.

7. The actuator unit of claim 1, wherein the actuator includes a piezoelectric element.

8. The actuator unit of claim 1, wherein the driving part includes:
a first portion configured to have the actuator mounted thereon and be insensitive to deformation due to driving force of the actuator; and
a second portion configured to be sensitive to the deformation due to the driving force of the actuator.

9. The actuator unit of claim 8, wherein the second portion is formed to be curved.

10. The actuator unit of claim 1, wherein the sensor includes a surface acoustic wave sensor.

11. The actuator unit of claim 10, wherein the surface acoustic wave sensor includes:
a piezoelectric substrate;
an input terminal electrode disposed on the piezoelectric substrate and configured to generate frequencies depending on deformation of the driving part; and
an output terminal electrode configured to transmit electrical signals by selectively reflecting a portion of the frequencies of the input terminal electrode.

12. The actuator unit of claim 10, wherein the surface acoustic wave sensor includes a sound-absorbing material blocking noise components from being transferred to the input terminal electrode and the output terminal electrode.

13. A lens module comprising:
a housing accommodating a lens;
an actuator unit including a support part supporting the lens, driving parts configured to adjust a gradient and/or a focal length of the lens, and actuators disposed on the driving parts; and
sensors configured to sense a change in a distance between the housing and the driving parts.

14. The lens module of claim 13, further comprising stoppers disposed in the housing to limit a maximum displacement of the driving parts.

15. The lens module of claim 13, further comprising magnetic bodies formed in the housing,
wherein the sensors are hall elements or piezoresistors sensing magnetic flux depending on a change in distance between the magnetic bodies and the driving parts.

16. The lens module of claim 13, wherein the sensors are piezoresistors configured to convert magnitudes of physical deformation of the driving parts into electrical signals.

17. The lens module of claim 13, wherein the actuator unit includes:
a first actuator unit disposed on a first surface of the lens; and
a second actuator unit disposed on a second surface of the lens.

18. The lens module of claim 17, wherein the driving part of the first actuator unit and the driving part of the second actuator unit are extended in different directions.

19. An adjustable planar lens module comprising:
a substrate including a peripherally defined fixing portion and a support portion, the support portion retaining a lens therein to be substantially coplanar with the substrate; and,
an electromechanical actuator extending longitudinally between the fixing portion and the support portion, the actuator being free on at least two longitudinally extending sides thereof and configured to selectively adjust an orientation of the lens and support portion relative to the fixing portion responsive to a driving signal.

20. The adjustable planar lens module of claim 19, wherein the electromechanical actuator is disposed on a deformable driving portion and a plurality of electrodes pass therethrough to electrically couple a sensor disposed proximate the support portion to the peripherally defined fixing portion.

21. The adjustable planar lens module of claim 19, wherein the electromechanical actuator is configured to adaptively adjust a focal distance and a gradient angle of the lens relative to the fixing portion.
